(19) United States
(12) Patent Application Publication
(10) Pub. No.: US 2024/0284712 A1
(43) Pub. Date: Aug. 22, 2024

(54) LIGHT EMITTING DISPLAY DEVICE

(71) Applicant: Samsung Display Co., LTD., Yongin-si (KR)

(72) Inventor: Yoo Mi RA, Yongin-si (KR)

(21) Appl. No.: 18/425,756

(22) Filed: Jan. 29, 2024

(30) Foreign Application Priority Data
Feb. 21, 2023 (KR) 10-2023-0023105

(51) Int. Cl. H10K 59/121; H10K 59/131

(52) U.S. Cl. CPC H10K 59/1216; H10K 59/1213; H10K 59/1315

(57) ABSTRACT

A light emitting display device including a first pixel, a second pixel, and a third pixel for emitting light of different colors, each of the first to third pixels including a lower storage electrode, an upper storage electrode overlapping the lower storage electrode and forming a storage capacitor with the lower storage electrode, and a pixel electrode overlapping the upper storage electrode, and wherein the upper storage electrode of the first pixel and the upper storage electrode of the third pixel are arranged in a first direction, and the upper storage electrodes of the first pixel and the third pixel and the upper storage electrode of the second pixel are arranged in a second direction crossing the first direction.

### CROSS-REFERENCE TO RELATED APPLICATION

This application claims priority to and the benefit of Korean Patent Application No. 10-2023-0023105 filed in the Korean Intellectual Property Office on Feb. 21, 2023, the entire content of which is incorporated herein by reference.

### BACKGROUND

### 1. Technical

Aspects of the present disclosure relate to a display device, and particularly relate to a light emitting display device including light emitting diodes.

### 2. Description of the Related Art

Currently display devices are in great use. These devices include, for example, light emitting display devices for displaying images by adjusting luminance of light-emitting devices, and liquid crystal displays for displaying images by adjusting transmittance of liquid crystal layers. The light emitting display device needs no additional light source such as a backlight, differing from the liquid crystal display, so a thickness and a weight of the display device may be reduced. Further, the light emitting diode displays exhibit high-quality characteristics such as low power consumption, high luminance, and high reaction rates. The light emitting display device may include a display area that corresponds to a screen for displaying images, and pixels may be disposed in the display area. The respective pixels may, as a light-emitting device, include a light emitting diode and a pixel circuit for driving the light emitting diode. The pixel circuit may include transistors and capacitors. As the resolution of a light emitting display device increases, the region in which pixel circuits of respective pixels are disposed may be reduced so interference among the pixels may be increased.

The above information disclosed in this Background section is only for enhancement of understanding of the background of the disclosure, and therefore it may contain information that does not form the prior art that is already known in this country to a person of ordinary skill in the art.

### SUMMARY

Aspects of embodiments of the present disclosure are directed to a light emitting display device capable of improving display quality and reducing defects by reducing interference among pixels.

According to some embodiments of the present disclosure, there is provided a light emitting display device including: a first pixel, a second pixel, and a third pixel for emitting light of different colors, each of the first to third pixels including: a lower storage electrode, an upper storage electrode overlapping the lower storage electrode and forming a storage capacitor with the lower storage electrode, and a pixel electrode overlapping the upper storage electrode, and wherein the upper storage electrode of the first pixel and the upper storage electrode of the third pixel are arranged in a first direction, and the upper storage electrodes of the first pixel and the third pixel and the upper storage electrode of the second pixel are arranged in a second direction crossing the first direction.

In some embodiments, lines connecting centers of the upper storage electrodes of the first pixel, the second pixel, and the third pixel form an acute-angled triangle, and a line connecting centers of the upper storage electrodes of the first pixel and the third pixel is parallel to the first direction, a line connecting centers of the upper storage electrodes of the first pixel and the second pixel forms an acute angle with respect to the first direction, and a line connecting centers of the upper storage electrodes of the second pixel and the third pixel forms an obtuse angle with respect to the first direction.

In some embodiments, the light emitting display device further includes: a first data line, a second data line, and a third data line extending in the second direction, and configured to transmit data voltages to the first pixel, the second pixel, and the third pixel, respectively, wherein the upper storage electrodes of the first pixel, the second pixel, and the third pixel are between the first data line and the second data line.

In some embodiments, the light emitting display device further includes: a driving voltage line extending in the second direction and configured to transmit a driving voltage, and an auxiliary driving voltage line extending in the first direction and connected to the driving voltage line, wherein each of the first pixel, the second pixel, and the third pixel includes a first transistor, the first transistor including a first semiconductor, a first gate electrode, a first electrode, and a second electrode, wherein the first gate electrode is connected to the upper storage electrode, and wherein the first electrode is a protrusion of the auxiliary driving voltage line.

In some embodiments, the first semiconductor includes a channel region, and a first region and a second region respectively on a first side and a second side of the channel region in the second direction, and a portion of the first gate electrode overlapping the first semiconductor extends in the first direction.

In some embodiments, the light emitting display device further includes: an auxiliary pattern overlapping the driving voltage line and connected to the driving voltage line, wherein the auxiliary pattern and the auxiliary driving voltage line are integrally formed.

In some embodiments, the light emitting display device further includes: a first gate line extending in the first direction and configured to transmit a first scan signal; a second gate line extending in the first direction and configured to transmit a second scan signal; an initialization voltage line extending in the second direction and configured to transmit an initialization voltage; and auxiliary initialization voltage line extending in the first direction and connected to the initialization voltage line, wherein the first gate line, the second gate line, and the auxiliary initialization voltage line are between the upper storage electrode of the second pixel and the upper storage electrodes of the first pixel and the third pixel.

In some embodiments, each of the first pixel, the second pixel, and the third pixel includes a second transistor, the second transistor including a second semiconductor and a second gate electrode, wherein in each of the first pixel, the second pixel, and the third pixel, the second semiconductor is integrally formed with the upper storage electrode, and wherein the second gate electrode of the first pixel and the second gate electrode of the third pixel are protrusions of the first gate line, and the second gate electrode of the second pixel is connected to the first gate line by a connector.

In some embodiments, each of the first pixel, the second pixel, and the third pixel further includes a third transistor, the third transistor including a third semiconductor and a third gate electrode, and the third gate electrode of the second pixel is a protrusion of the second gate line, and the third gate electrode of the first pixel and the third gate electrode of the third pixel are connected to the second gate line by a connector.

In some embodiments, the light emitting display device further includes: a common voltage line extending in the second direction and configured to transmit a common voltage; an auxiliary pattern connected to and overlapping the common voltage line; a connection electrode connected to and overlapping the auxiliary pattern; and an auxiliary common voltage line extending in the first direction and integrally formed with the connection electrode.

According to some embodiments of the present disclosure, there is provided a light emitting display device including a unit pixel including a first pixel, a second pixel, and a third pixel for emitting light of different colors, the unit pixel further including: a substrate; lower storage electrodes of the first, second, and third pixels on the substrate; a first insulating layer on the lower storage electrodes; upper storage electrodes of the first, second, and third pixels on the first insulating layer; a third insulating layer on the upper storage electrodes; a fourth insulating layer on the third insulating layer; pixel electrodes of the first, second, third pixels on the fourth insulating layer and overlapping the upper storage electrodes; and a fifth insulating layer having openings overlapping the pixel electrodes, wherein the upper storage electrode of the first pixel overlaps the upper storage electrode of the third pixel in a first direction, and the upper storage electrodes of the first and third pixels overlap the upper storage electrode of the second pixel in a second direction crossing the first direction.

In some embodiments, lines connecting centers of the upper storage electrodes of the first, second, and third pixels form an acute-angled triangle, and a line connecting centers of the upper storage electrodes of the first and third pixels is parallel to the first direction, a line connecting centers of the upper storage electrodes of the first and second pixels forms an acute angle with respect to the first direction, and a line connecting centers of the upper storage electrodes of the second and third pixels forms an obtuse angle with respect to the first direction.

In some embodiments, the light emitting display device further includes: a first data line, a second data line, and a third data line extending in the second direction between the substrate and the first insulating layer, and configured to transmit data voltages to the first pixel, the second pixel, and the third pixel, respectively, and wherein the upper storage electrodes of the first, second, and third pixels are between the first data line and the second data line in a plan view.

In some embodiments, the light emitting display device further includes: a driving voltage line extending in the second direction between the substrate and the first insulating layer and configured to transmit a driving voltage; a second insulating layer between the first insulating layer and the third insulating layer; and an auxiliary driving voltage line extending in the first direction between the second insulating layer and the third insulating layer and connected to the driving voltage line, wherein each of the first, second, and third pixels includes a first transistor including a first semiconductor, a first gate electrode, a first electrode, and a second electrode, and wherein the first electrode is a protrusion of the auxiliary driving voltage line.

In some embodiments, the first semiconductor is between the first insulating layer and the second insulating layer, the first semiconductor includes a channel region, and a first region and a second region respectively on a first side and a second side of the channel region in the second direction, and a portion of the first gate electrode overlapping the first semiconductor extends in the first direction.

In some embodiments, the light emitting display device further includes: an auxiliary pattern between the second insulating layer and the third insulating layer and connected to the driving voltage line and the auxiliary driving voltage line.

In some embodiments, the light emitting display device further includes: a first gate line extending in the first direction between the second insulating layer and the third insulating layer and configured to transmit a first scan signal; a second gate line extending in the first direction between the second insulating layer and the third insulating layer and configured to transmit a second scan signal; an initialization voltage line extending in the second direction between the substrate and the first insulating layer and configured to transmit an initialization voltage; and an auxiliary initialization voltage line extending in the first direction between the second insulating layer and the third insulating layer and connected to the initialization voltage line, wherein the first gate line, the second gate line, and the auxiliary initialization voltage line are between the upper storage electrode of the second pixel and the upper storage electrodes of the first and third pixels in a plan view.

In some embodiments, each of the first, second, and third pixels includes a second transistor the second transistor including a second semiconductor and a second gate electrode, wherein in each of the first, second, and third pixels, the second semiconductor is integrally formed with the upper storage electrode, wherein the second gate electrode of the first pixel and the second gate electrode of the third pixel are protrusions of the first gate line, and wherein the second gate electrode of the second pixel is connected to the first gate line by a connector between the substrate and the first insulating layer.

In some embodiments, each of the first, second, and third pixels further includes a third transistor, the third transistor including a third semiconductor and a third gate electrode, and the third gate electrode of the second pixel is a protrusion of the second gate line, and the third gate electrode of the first pixel and the third gate electrode of the third pixel are connected to the second gate line by a connector between the substrate and the first insulating layer.

In some embodiments, the light emitting display device further includes: a common voltage line extending in the second direction between the substrate and the first insulating layer and configured to transmit a common voltage; an auxiliary pattern between the first insulating layer and the third insulating layer and connected to the common voltage line; a connection electrode on the fourth insulating layer and connected to the auxiliary pattern; and an auxiliary common voltage line extending in the first direction on the fourth insulating layer and connected to the connection electrode.

According to some embodiments, the light emitting display device capable of improving display quality and reducing defects by reducing interference among pixels is provided. According to some embodiments, the display device capable of reducing power resistance is provided.

### BRIEF DESCRIPTION OF THE DRAWINGS

FIG. 1 shows a top plan view of a light emitting display device according to some embodiments of the present disclosure.

FIG. 2 shows a circuit diagram of a pixel of a light emitting display device according to some embodiments of the present disclosure.

FIG. 3 shows a top plan view of a pixel area of a light emitting display device according to some embodiments of the present disclosure.

FIG. 4 shows a cross-sectional view with respect to the line A-A′ of FIG. 3, according to some embodiments of the present disclosure.

FIG. 5 shows a cross-sectional view with respect to a line B-B′ of FIG. 3, according to some embodiments of the present disclosure.

FIG. 6, FIG. 7, FIG. 8, and FIG. 9 show top plan views of the light emitting display device shown in FIG. 3 in a manufacturing order, according to some embodiments of the present disclosure.

FIG. 10 shows a cross-sectional view of a display area in a light emitting display device according to some embodiments of the present disclosure.

### DETAILED DESCRIPTION

The present disclosure will be described more fully hereinafter with reference to the accompanying drawings, in which embodiments are shown.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

Symbols “x”, “y”, and “z” are used to indicate directions, and here, “x” is a first direction, “y” is a second direction perpendicular to the first direction, and “z” is a third direction perpendicular to the first and the second directions. The first direction x, the second direction y, and the third direction z may correspond to a horizontal direction, a vertical direction, and a thickness direction of the display device.

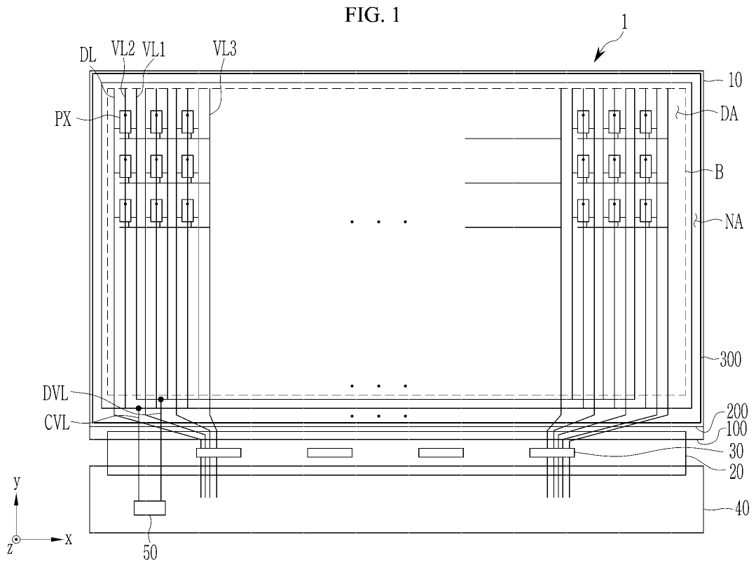

FIG. 1 shows a top plan view of a light emitting display device according to some embodiments of the present disclosure.

Referring to FIG. 1, the light emitting display device 1 (also simply referred to as a display device) may include a display panel 10, a flexible printed circuit film 20, a driving integrated circuit chip 30, a printed circuit board (PCB) 40, and a power module 50.

The display panel 10 may include a display area DA that corresponds to a screen for displaying images, and a non-display area NA in which circuits and/or wires for generating and/or transmitting various signals applied to the display area DA are disposed. The non-display area NA may be near the display area DA and may surround the display area DA. Referring to FIG. 1, an internal region and an external region of the border line B may be the display area DA and the non-display area NA, respectively.

The display panel 10 may include a display unit 100 and a color conversion unit 200. The display unit 100 and the color conversion unit 200 may be bonded by a sealant 300 surrounding an edge of the display panel 10 between the display unit 100 and the color conversion unit 200. The color conversion unit 200 may entirely overlap the display unit 100, and the display unit 100 may include a region not covered by the color conversion unit 200 for the purpose of connection or bonding of the flexible printed circuit film 20. The display unit 100 may include a pad portion for connecting or bonding of the flexible printed circuit film 20, and the color conversion unit 200 may be formed to be shorter than the display unit 100 in a region in which the pad portion is disposed, for example, at a lower end of the display panel 10 so that the pad portion may be exposed to the outside. The display unit 100 and the color conversion unit 200 may include regions that correspond to the display area DA and the non-display area NA of the display panel 10.

Pixels PX may be disposed as a matrix in the display area DA of the display panel 10. A data line DL for transmitting a data voltage V_{DATA}, a driving voltage line VL1 for transmitting a driving voltage EL_{VDD}, a common voltage line VL2 for transmitting a common voltage EL_{VSS}, and an initialization voltage line VL3 for transmitting an initialization voltage V_{INT} may be disposed in the display area DA. The driving voltage line VL1, the common voltage line VL2, and the initialization voltage line VL3 may extend in a second direction y. The driving voltage line VL1, the common voltage line VL2, and/or the initialization voltage line VL3 may be connected to an auxiliary voltage line extending in a first direction x. The respective pixels PX may receive the data voltage V_{DATA}, the driving voltage EL_{VDD}, the common voltage EL_{VSS}, and the initialization voltage V_{INT} from the voltage lines DL, VL1, VL2, and VL3, respectively. The driving voltage EL_{VDD} and the common voltage EL_{VSS} are power voltage applied to the respective pixels PX, and the driving voltage line VL1 and the common voltage line VL2 for transmitting the power voltages may be referred to as power voltage lines. The driving voltage EL_{VDD} may be higher than the common voltage EL_{VSS}. The driving voltage EL_{VDD} may be referred to as a first power voltage or a high-potential power voltage. The common voltage EL_{VSS} may be referred to as a second power voltage or a low-potential power voltage.

Gate drivers may be disposed on respective sides of the display area DA in the non-display area NA of the display panel 10. The gate drivers may be integrated in the non-display area NA. The pixels PX may receive a gate signal (also referred to as a scan signal) generated by the gate driver and may receive the data voltage V_{DATA} at a set or predetermined timing.

A driving voltage transmitting line DVL connected to the driving voltage lines VL1 and a common voltage transmitting line CVL connected to the common voltage lines VL2 may be disposed in the non-display area NA of the display panel 10. The driving voltage transmitting line DVL and the common voltage transmitting line CVL may include portions extending in the second direction y and portions extending in the first direction x. The common voltage transmitting line CVL may be disposed to surround the display area DA. The common voltage lines VL2 may be connected to the common voltage transmitting line CVL on an upper side and a lower side of the display area DA, and thus, the common voltage EL_{VSS} may be uniformly supplied to the display area DA.

The flexible printed circuit film 20 includes a first end connected/bonded to the display unit 100 of the display panel 10 and a second end connected/bonded to the printed circuit board 40. A driving integrated circuit chip 30 including a data driver for applying the data voltage V_{DATA} to the data line DL may be disposed on the flexible printed circuit film 20.

A power module 50 for generating power voltages including the driving voltage EL_{VDD} and the common voltage EL_{VSS} may be disposed on the printed circuit board 40. The power module 50 may have an integrated circuit chip form. A signal controller for controlling the data driver and the gate driver may be disposed on the printed circuit board 40.

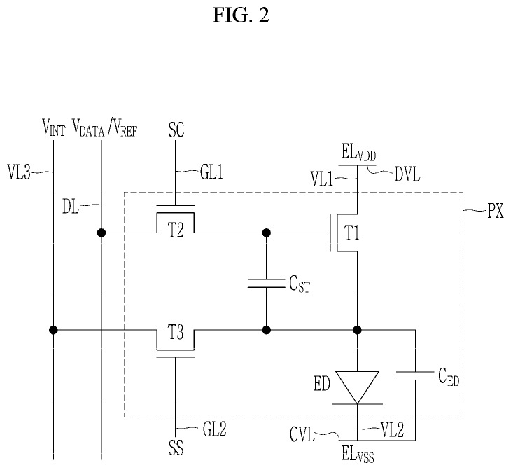

FIG. 2 shows a circuit diagram of a pixel of a light emitting display device according to some embodiments of the present disclosure.

Referring to FIG. 2, the pixel PX may include first, second, and third transistors T1, T2, and T3, a storage capacitor C_{ST}, and a light-emitting device ED. The pixel PX may further include a light-emitting device capacitor C_{ED} connected to respective ends of the light-emitting device ED. The light-emitting device ED may be an organic or inorganic light emitting diode. The first, second and third transistors T1, T2, and T3 may be n-type transistors, and at least part thereof may be p-type transistors. The first, second, and third transistors T1, T2, and T3 may respectively include a gate electrode, a first electrode, and a second electrode. One of the first electrode and the second electrode may be a source electrode, and the other thereof may be a drain electrode.

A gate electrode of the first transistor T1 may be connected to a first electrode of the storage capacitor C_{ST}. A first electrode of the first transistor T1 may be connected to the driving voltage line VL1 for transmitting the driving voltage EL_{VDD}, a second electrode of the first transistor T1 may be connected to an anode of the light-emitting device ED and a second electrode of the storage capacitor C_{ST}. The first transistor T1 may receive the data voltage (V_{DATA}) according to a switching operation of the second transistor T2 and may supply a driving current to the light-emitting device ED according to the voltage stored in the storage capacitor C_{ST}. The first transistor T1 may be referred to as a driving transistor.

A gate electrode of the second transistor T2 may be connected to the first gate line GL1 for transmitting the first scan signal SC. A first electrode of the second transistor T2 may be connected to the data line DL for transmitting the data voltage V_{DATA} or a reference voltage V_{REF}. A second electrode of the second transistor T2 may be connected to the first electrode of the storage capacitor C_{ST} and the gate electrode of the first transistor T1. The second transistor T2 may be turned on according to a first scan signal SC and may transmit the reference voltage V_{REF} or the data voltage V_{DATA} to the gate electrode of the first transistor T1.

A gate electrode of the third transistor T3 may be connected to a second gate line GL2 for transmitting a second scan signal SS. A first electrode of the third transistor T3 may be connected to an initialization voltage line VL3 for transmitting the initialization voltage V_{INT}. A second electrode of the third transistor T3 may be connected to a second electrode of the storage capacitor C_{ST}, and the second electrode and the anode of the first transistor T1. The third transistor T3 may be turned on according to the second scan signal SS and may transmit the initialization voltage V_{INT} to the anode to initialize the voltage at the anode.

The first electrode of the storage capacitor C_{ST} may be connected to the gate electrode of the first transistor T1, and the second electrode of the storage capacitor C_{ST} may be connected to the second electrode and the anode of the third transistor T3. A cathode of the light-emitting device ED may be connected to the common voltage line VL2 for transmitting the common voltage EL_{VSS}. The respective light-emitting devices ED may constitute a pixel PX, and the anode and the cathode of the light-emitting device ED may be respectively referred to as a pixel electrode and a common electrode.

The light-emitting device ED may emit light with luminance (or grayscale) according to the driving current generated by the first transistor T1. The light-emitting device capacitor C_{ED} may maintain a voltage at the light-emitting device ED so that the light-emitting device ED may emit light with constant luminance.

An operation of the circuit shown in FIG. 2, particularly the operation for one frame will now be described with the case when the transistors T1, T2, and T3 are n-type transistors as an example.

When one frame starts, the common voltage EL_{VSS} may be applied as a high-level voltage while the first scan signal SC and the second scan signal SS have a low level during the initialization period (e.g., the initialization phase). As a result, no current flows through the light-emitting device ED to prevent the light-emitting device ED from emitting light. The initialization voltage V_{INT} is applied through the initialization voltage line VL3 to initialize the initialization voltage line VL3. A high-level first scan signal SC and a high-level second scan signal SS are supplied to turn on the second transistor T2 and the third transistor T3. The reference voltage V_{REF} applied from the data line DL may be supplied to the gate electrode of the transistor T1 and the first electrode of the first storage capacitor C_{ST} through the activated/turned-on second transistor T2, and the initialization voltage V_{INT} may be supplied to the second electrode and the anode of the first transistor T1 through the activated/turned-on third transistor T3. Hence, during the initialization period, the anode may be initialized to be the initialization voltage V_{INT}. The storage capacitor C_{ST} may store a voltage difference V_{REF}−V_{INT} between the reference voltage V_{REF} and the initialization voltage V_{INT}.

During a sensing period (e.g., a sensing phase), the high-level first scan signal SC and the high-level second scan signal SS may be maintained. The initialization voltage line VL3 may be disconnected from a supply source of the initialization voltage V_{INT}, and may function as a sensing line. The gate electrode of the first transistor T1 and the first electrode of the storage capacitor C_{ST} may maintain the reference voltage V_{REF} through the second transistor T2. Hence, when the current flows to the second electrode of the first transistor T1 from the first electrode, and the voltage at the second electrode becomes the difference between the reference voltage V_{REF} and the threshold voltage V_{TH} (i.e., “reference voltage V_{REF}−threshold voltage V_{TH}”), the first transistor T1 may be turned off, and the initialization voltage line VL3 may be charged up to the difference voltage (i.e., “reference voltage V_{REF}−threshold voltage V_{TH}”). Here, the threshold voltage V_{TH} indicates the threshold voltage V_{TH} of the first transistor T1. The initialization voltage line VL3 charged with this difference voltage may be connected to an external circuit, and the external circuit may sense the voltage of the initialization voltage line VL3 and may extract the threshold voltage V_{TH} of the first transistor T1. The characteristic deviations of the first transistor T1 that may be different for the respective pixels PX may be compensated by reflecting characteristic information sensed for the sensing period and generating a compensated data signal.

during a data input period (e.g., a data input phase), a high-level first scan signal SC may be supplied and a low-level second scan signal SS may be supplied, and the data voltage V_{DATA} provided from the data line DL may be supplied to the gate electrode of the first transistor T1 and the first electrode of the storage capacitor C_{ST} through the activated/turned-on second transistor T2. The data voltage V_{DATA} may have a compensated value based on the sensing of the threshold voltage V_{TH} of the first transistor T1, and the characteristic deviation of the first transistor T1 may be corrected. When the data voltage V_{DATA} is applied, the second electrode and the anode of the first transistor T1 may substantially maintain the potential for the sensing period by the deactivated/turned-off first transistor T1.

During an emission period (e.g., an emission phase), the first transistor T1 turned on by the data voltage V_{DATA} transmitted to the gate electrode of the first transistor may generate a driving current according to the data voltage V_{DATA}, and the light-emitting device ED may emit light by the driving current. That is, luminance of the light-emitting device ED may be adjusted by adjusting the driving current applied to the light-emitting device ED according to a size of the data voltage V_{DATA} applied to the pixel PX.

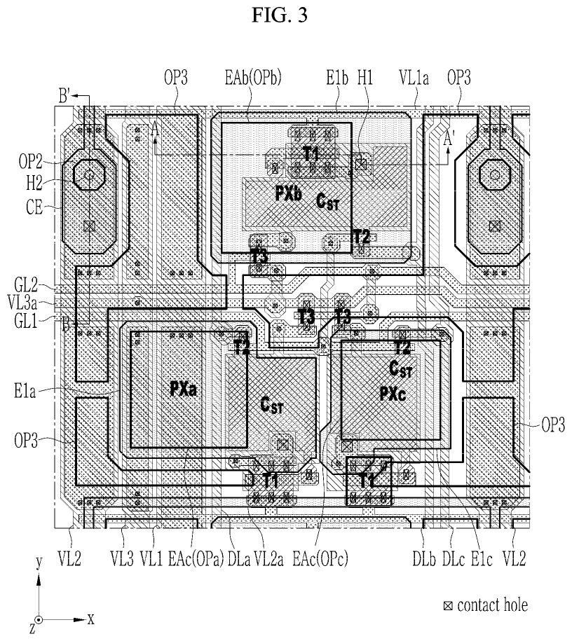

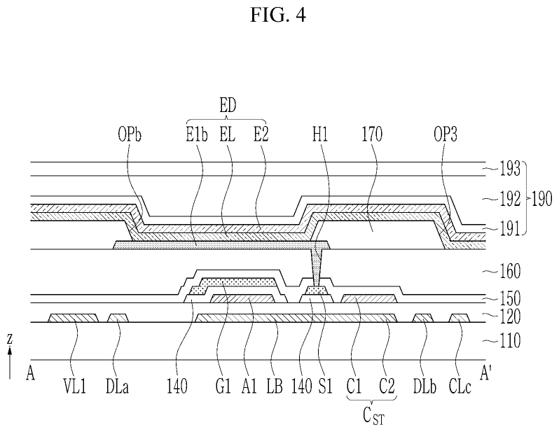

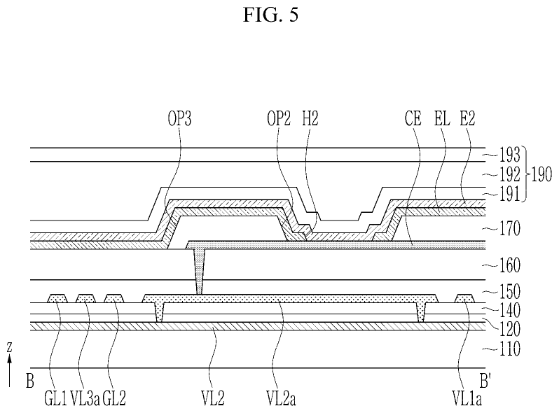

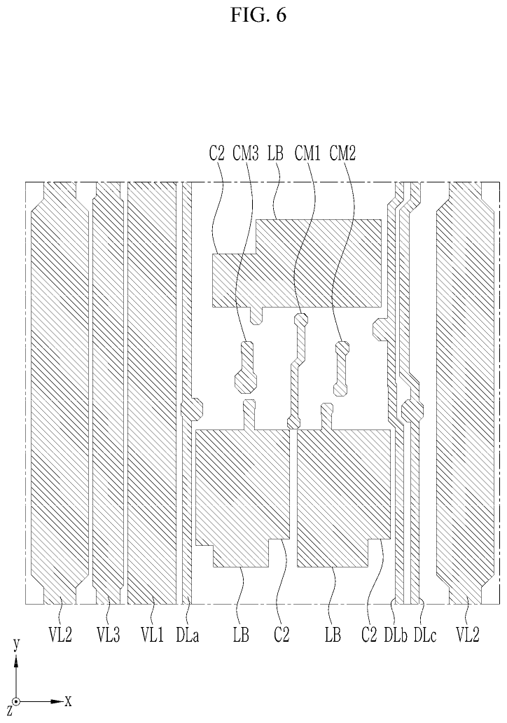

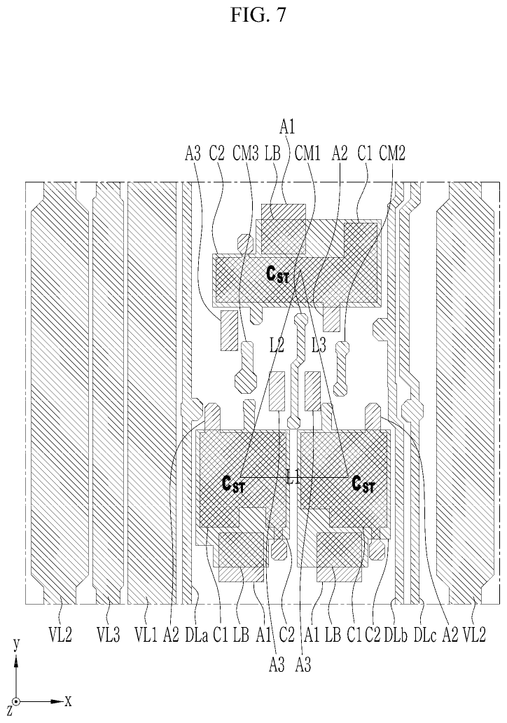

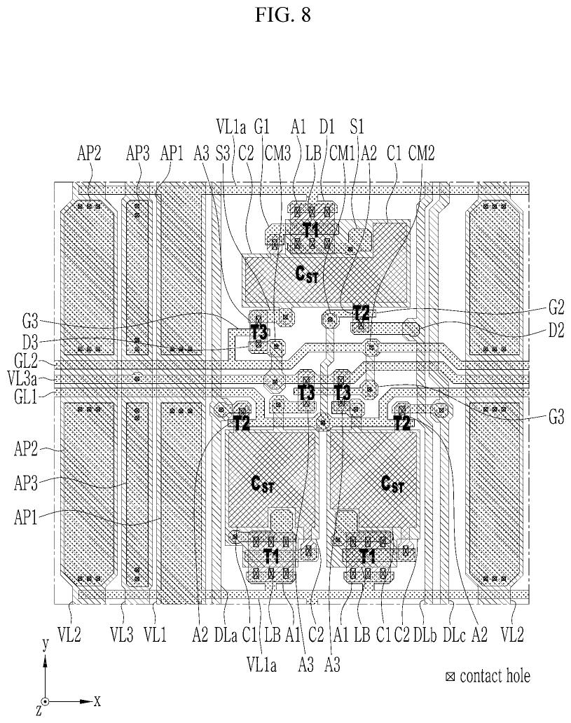

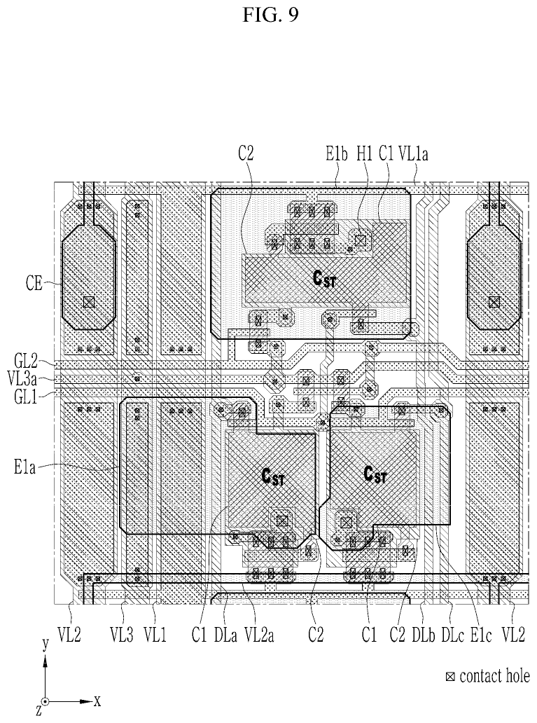

FIG. 3 shows a top plan view of a pixel area of a light emitting display device according to some embodiments of the present disclosure; FIG. 4 shows a cross-sectional view with respect to the line A-A′ of FIG. 3, according to some embodiments of the present disclosure; and FIG. 5 shows a cross-sectional view with respect to the line B-B′ of FIG. 3, according to some embodiments of the present disclosure. FIGS. 6 to 9 show top plan views of a light emitting display device shown in FIG. 3 in a manufacturing order.

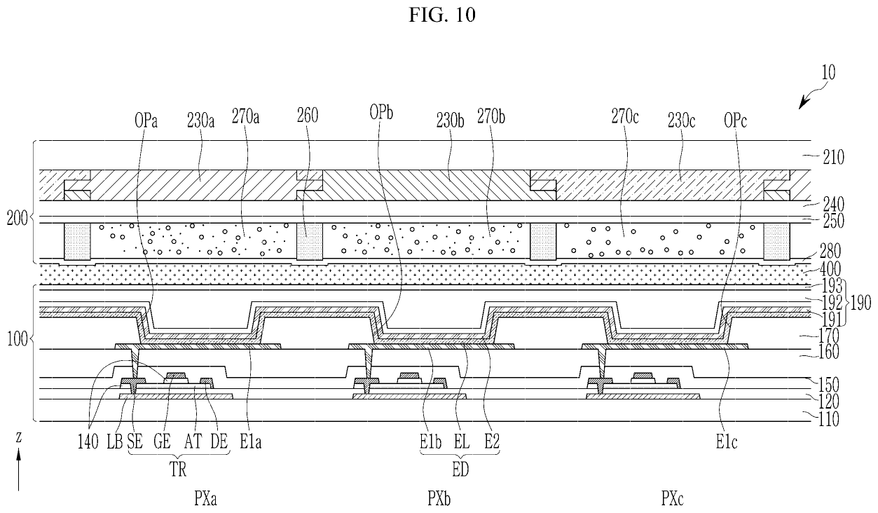

FIG. 3 shows three adjacent pixels PXa, PXb, and PXc and wires connected thereto on a display panel 10 included by a display device according to some embodiments. The pixels PXa, PXb, and PXc may be repeatedly disposed in the first direction x and the second direction y. A display unit 100 of the display panel 10 will be described below, and a color conversion unit 200 of the display panel 10 will be described later with reference to FIG. 10.

Referring to FIGS. 3 to 9, the pixels PXa, PXb, and PXc may include a first pixel PXa, a second pixel PXb, and a third pixel PXc emitting light of different colors. One of the first pixel PXa, the second pixel PXb, and the third pixel PXc may display red, another may display green, and the other may display blue. For example, the first pixel PXa, the second pixel PXb, and the third pixel PXc may respectively display red, green, and blue colors. The first pixel PXa, the second pixel PXb, and the third pixel PXc may constitute a unit pixel. Combinations of the first pixel PXa, the second pixel PXb, and the third pixel PXc may display various colors.

The respective pixels PXa, PXb, and PXc may include emission areas EAa, EAb, and EAc for emitting light. The respective emission areas EAa, EAb, and EAc may have a rectangular shape in a plan view. The pixels PXa, PXb, and PXc may be disposed so that lines connecting centers of the emission areas EAa, EAb, and EAc may form a triangle. For example, the line connecting the center of the emission area EAa of the first pixel PXa and the center of the emission area EAc of the third pixel PXc may be parallel to the first direction x. The line connecting the center of the emission area EAb of the second pixel PXb and the center of the emission area EAa of the first pixel PXa may form an acute angle with respect to the first direction x, and the line connecting the center of the emission area EAb of the second pixel PXb and the center of the emission area EAc of the third pixel PXc may form an obtuse angle with respect to the first direction x. The lines connecting the centers of the emission areas EAa, EAb, and EAc of the pixels PXa, PXb, and PXc may form an acute-angled triangle, for example, they may substantially form an isosceles triangle.

The display unit 100 may include a substrate 110, first, second, and third transistors T1, T2, and T3 and a storage capacitor C_{ST} formed on the substrate 110, and a light-emitting device ED connected to the first transistor T1.

The substrate 110 may include a rigid material such as glass and/or the like, or a flexible material such as plastic and/or the like. For example, the substrate 110 may be a glass substrate. The substrate 110 may include a polymer material such as a polyimide, a polyamide, a polyethylene terephthalate, and/or the like.

A first conductive layer including data lines DLa, DLb, and DLc, a driving voltage line VL1, a common voltage line VL2, an initialization voltage line VL3, a second storage electrodes C2, light blocking patterns LB, and connectors CM1, CM2, and CM3 may be disposed on the substrate 110. FIG. 6 shows a first conductive layer.

The data lines DLa, DLb, and DLc may include a first data line DLa for transmitting a data voltage V_{DATA} to the first pixel PXa, a second data line DLb for transmitting a data voltage V_{DATA} to the second pixel PXb, and a third data line DLc for transmitting a data voltage V_{DATA} to the third pixel PXc. The first data line DLa, the second data line DLb, and the third data line DLc may extend (e.g., longitudinally) in the second direction y. The first data line DLa may be spaced from (e.g., offset from) the second data line DLb with the second storage electrodes C2 therebetween. The second data line DLb may be disposed near the third data line DLc in the first direction x.

The driving voltage line VL1 may transmit the driving voltage EL_{VDD}, the common voltage line VL2 may transmit the common voltage EL_{VSS}, and the initialization voltage line VL3 may transmit the initialization voltage V_{INT}. The driving voltage line VL1, the common voltage line VL2, and the initialization voltage line VL3 may each extend (e.g., longitudinally) in the second direction y.

The common voltage line VL2, the initialization voltage line VL3, the driving voltage line VL1, and the data lines DLa, DLb, and DLc may be disposed in the first direction x. Accordingly, in the first direction x, the driving voltage line VL1 may be disposed between the initialization voltage line VL3 and the data lines DLa, DLb, and DLc, the common voltage line VL2 may be disposed between the data lines DLa, DLb, and DLc and the initialization voltage line VL3, and the initialization voltage line VL3 may be disposed between the common voltage line VL2 and the driving voltage line VL1. Relative disposition among the voltage lines VL1, VL2, and VL3 and the data lines DLa, DLb, and DLc may be changed in many suitable ways.

The second storage electrodes C2 may be disposed between the first data line DLa and the second data line DLb. The second storage electrodes C2 may be second electrodes of the storage capacitors C_{ST} of the respective pixels PXa, PXb, and PXc.

The light blocking patterns LB may be disposed between the first data line DLa and the second data line DLb. The light blocking patterns LB may prevent or substantially reduce deterioration of the characteristic of the semiconductor A1 by preventing external light from reaching the semiconductors A1 of the first transistors T1 of the respective pixels PXa, PXb, and PXc, or substantially reduce instances thereof. The leakage current of the first transistor T1, particularly the driving transistor whose current characteristic is important in the light emitting display device may be controlled by the light blocking patterns LB. The light blocking pattern LB may function as an electrode for receiving a specific voltage. In this case, a rate of current change in a saturation region becomes small, so the characteristic of the driving transistor may be increased in the voltage-current characteristic graph of the first transistor T1. Regarding the respective pixels PXa, PXb, and PXc, the light blocking pattern LB and the second storage electrode C2 may be integrally formed (e.g., formed as a unitary body).

The connector CM1 may electrically connect the first gate line GL1 and the gate electrode G2 of the second transistor T2 of the second pixel PXb. The connector CM2 may electrically connect the second gate line GL2 and the gate electrodes G3 of the third transistors T3 of the first and third pixels PXa and PXc. The connector CM3 may electrically connect the auxiliary initialization voltage line VL3a and the first electrode D3 of the third transistor T3 of the second pixel PXb.

Constituent elements formed by the first conductive layer may be formed of a same or substantially the same material by the same process. For example, a conductive layer may be deposited and patterned on the substrate 110 to form data lines DLa, DLb, and DLc, a driving voltage line VL1, a common voltage line VL2, an initialization voltage line VL3, a second storage electrodes C2, a light blocking patterns LB, and connectors CM1, CM2, and CM3. The first conductive layer may include a metal such as copper (Cu), aluminum (Al), titanium (Ti), molybdenum (Mo), tungsten (W), and/or the like, and may have a single layer or a multi-layer structure. For example, the first conductive layer may have a double-layered structure such as titanium (Ti)/copper (Cu).

A first insulating layer 120 may be disposed on the first conductive layer. The first insulating layer 120 may be referred to as a buffer layer. The first insulating layer 120 may block impurities from the substrate 110 when forming the semiconductor layer to increase the characteristic of the semiconductor layer, and may planarize a surface of the substrate 110 to ease a stress of the semiconductor layer. The first insulating layer 120 may include an inorganic insulating material such as a silicon nitride (SiNₓ), a silicon oxide (SiOₓ), a silicon oxynitride (SiOₓN_{y}), and/or the like.

A semiconductor layer including semiconductors A1, A2, and A3 may be disposed on the first insulating layer 120. The semiconductor layer may further include a first storage electrodes C1. FIG. 7 shows the first conductive layer and the semiconductor layer.

The semiconductors A1, A2, and A3 may include a semiconductor A1 of the first transistor T1, a semiconductor A2 of the second transistor T2, and a semiconductor A3 of the third transistor T3. The respective semiconductors A1, A2, and A3 may include a first region, a second region, and a channel region between the first and second regions. The first region and the second region may be disposed on a first side and a second side of the channel region in the second direction y in each of the semiconductors A1, A2, and A3. The first region of the semiconductor A1 may be connected to an auxiliary driving voltage line VL1a for transmitting the driving voltage EL_{VDD}. The second region and the channel region of the semiconductor A1 may overlap the light blocking pattern LB. The first region of the semiconductor A2 may be connected to the data lines DLa, DLb, and DLc. That is, the first region of the semiconductor A1 of the first pixel PXa may be connected to the first data line DLa, the first region of semiconductor A2 of the second pixel PXb may be connected to the second data line DLb, and the first region of the semiconductor A3 of the third pixel PXc may be connected to the third data line DLc. The second region of the semiconductor A2 may be connected to the first storage electrode C1. The semiconductor A2 and the first storage electrode C1 may be integrally formed (e.g., formed as a unitary body). The first region of the semiconductor A3 may be connected to the auxiliary initialization voltage line VL3a for transmitting the initialization voltage V_{INT}. The second region of the semiconductor A3 may be connected to the second storage electrode C2.

Regarding the respective pixels PXa, PXb, and PXc, the first storage electrode C1 may overlap the second storage electrode C2 to constitute the storage capacitor C_{ST}. The first storage electrode C1 and the second storage electrode C2 may be referred to as an upper storage electrode and a lower storage electrode, respectively. The first storage electrode C1 may be the first electrode of the storage capacitor C_{ST}. The first storage electrode C1 may be disposed between the semiconductor A1 of the second pixel PXb and the semiconductors A1 of the first and third pixels PXa and PXc in the second direction y. The first storage electrodes C1 of the first and third pixels PXa and PXc may be arranged to overlap each other in the first direction x. The first storage electrodes C1 of the first and third pixels PXa and PXc may be arranged to overlap the first storage electrode C1 of the second pixel PXb in the second direction y. A sum of widths of the first storage electrode C1 of the first pixel PXa and the first storage electrode C1 of the third pixel PXc may be greater than a width of the first storage electrode C1 of the second pixel PXb in the first direction x. The first storage electrode C1 of the second pixel PXb may include a portion overlapping the semiconductor A1 of the second pixel PXb in the first direction x.

The storage capacitors C_{ST} of the pixels PXa, PXb, and PXc may be disposed so that the lines L1, L2, and L3 connecting the centers of the first storage electrodes C1 may form a triangle. For example, the line L1 connecting the center of the first storage electrode C1 of the first pixel PXa and the center of the first storage electrode C1 of the third pixel PXc may be substantially parallel to the first direction x. The line L2 connecting the center of the first storage electrode C1 of the second pixel PXb and the center of the first storage electrode C1 of the first pixel PXa may form an acute angle with respect to the first direction x, and the line L3 connecting the center of the first storage electrode C1 of the second pixel PXb and the center of the first storage electrode C1 of the third pixel PXc may form an obtuse angle with respect to the first direction x. The lines L1, L2, and L3 connecting the centers of the first storage electrodes C1 of the pixels PXa, PXb, and PXc may form an acute-angled triangle, for example, they may substantially form an isosceles triangle.

The constituent elements included by the semiconductor layer may be formed of a same material by the same process. The semiconductor layer may include an oxide semiconductor. For example, the semiconductor layer may include an oxide semiconductor, such as an indium-gallium-zinc oxide (IGZO), including at least one of zinc (Zn), indium (In), gallium (Ga), tin (Sn), and mixtures thereof. The semiconductor layer may include polycrystalline silicon or amorphous silicon, for example, it may include low-temperature polysilicon (LTPS).

A second insulating layer 140 may be disposed on the semiconductor layer. The second insulating layer 140 may be referred to as a gate insulating layer. The second insulating layer 140 may be formed in a region overlapping the second conductive layer. The second insulating layer 140 may be formed to cover the substantially substrate 110. The second insulating layer 140 may be an inorganic insulating layer including an inorganic insulating material such as a silicon oxide, a silicon nitride, a silicon oxynitride, and/or the like, and may have a single layer or a multi-layer structure.

A second conductive layer including gate electrodes G1, G2, and G3, first electrodes D1, D2, and D3, second electrodes S1, S2, and S3, a first gate line GL1, a second gate line GL2, an auxiliary driving voltage line VL1a, an auxiliary initialization voltage line VL3a, and auxiliary patterns AP1, AP2, and AP3 may be disposed on the second insulating layer 140. FIG. 8 shows the first conductive layer, the semiconductor layer, and the second conductive layer.

The gate electrodes G1, G2, and G3 may include the gate electrode G1 of the first transistor T1, the gate electrode G2 of the second transistor T2, and the gate electrode G3 of the third transistor T3. The gate electrodes G1, G2, and G3 may overlap the channel regions of the corresponding semiconductors A1, A2, and A3. A portion of the gate electrode G1 overlapping the semiconductor A1 may extend (e.g., longitudinally) in the first direction x. The gate electrode G1 may be connected to a protrusion of the first storage electrode C1 through a contact hole formed in the second insulating layer 140. The gate electrode G2 of the second pixel PXb may be connected to the connector CM1 through contact holes formed in the first and second insulating layers 120 and 140. The gate electrodes G2 of the first and third pixels PXa and PXc may be protrusions of the first gate line GL1. The gate electrode G3 of the second pixel PXb may be the protrusion of the second gate line GL2. The gate electrodes G3 of the first and third pixels PXa and PXc may be integrally formed (e.g., formed as a unitary body), and may be connected to the connector CM3 through contact holes formed in the first and second insulating layers 120 and 140.

The first electrodes D1, D2, and D3 may include a first electrode D1 of the first transistor T1, a first electrode D2 of the second transistor T2, and a first electrode D3 of the third transistor T3. The first electrode D1 may be a protrusion of the auxiliary driving voltage line VL1a. The first electrode D2 may be connected to the corresponding data lines DLa, DLb, and DLc through contact holes formed in the first and second insulating layers 120 and 140. The first electrode D3 of the second pixel PXb may be connected to the connector CM3. The first electrodes D3 of the first and third pixels PXa and PXc may be part of the auxiliary initialization voltage line VL3a and may be connected to the third semiconductors A3 through contact holes formed in the second insulating layer 140.

The second electrodes S1, S2, and S3 may include a second electrode S1 of the first transistor T1, a second electrode S2 of the second transistor T2, and a second electrode S3 of the third transistor T3. The second electrode S1 may be connected to the semiconductor A1 through a contact hole formed in the second insulating layer 140. The second electrode S1 may be connected to the light blocking pattern LB through the contact holes formed in the first and second insulating layers 120 and 140. The second electrode S2 may be connected to the first storage electrode C1. The second electrode S2 and the first storage electrode C1 may be integrally formed (e.g., formed as a unitary body). The second electrode S3 may be connected to the third semiconductor A3 through the contact hole formed in the second insulating layer 140 and may be connected to the second storage electrode C2 through the contact holes formed in the first and second insulating layers 120 and 140.

The first gate line GL1, the second gate line GL2, the auxiliary driving voltage line VL1a, and the auxiliary initialization voltage line VL3a may extend (e.g., longitudinally) in the first direction. The first gate line GL1, the second gate line GL2, and the auxiliary initialization voltage line VL3a may be disposed between the second pixel PXb and the first and third pixels PXa and PXc. The auxiliary initialization voltage line VL3a may be disposed between the first gate line GL1 and the second gate line GL2. The first gate line GL1 may be connected to the connector CM1 through the contact holes formed in the first and second insulating layers 120 and 140. Hence, the gate electrode G2 of the second pixel PXb may be electrically connected to the first gate line GL1. The second gate line GL2 may be connected to the connector CM2 through the contact holes formed in the first and second insulating layers 120 and 140. Accordingly, the gate electrodes G3 of the first and third pixels PXa and PXc may be electrically connected to the second gate line GL2.

The auxiliary initialization voltage line VL3a may be connected to the initialization voltage line VL3 through the contact holes formed in the first and second insulating layers 120 and 140. Accordingly, the initialization voltage line VL3 and the auxiliary initialization voltage line VL3a may be disposed in a mesh form, and the initialization voltage V_{INT} at the uniform level may be transmitted to the display area DA. The auxiliary initialization voltage line VL3a may be connected to the third semiconductors A3 of the first and third pixels PXa and PXc through the contact holes formed in the first and second insulating layers 120 and 140. The auxiliary initialization voltage line VL3a may be connected to the connector CM3 through the contact holes formed in the first and second insulating layers 120 and 140. Hence, the first electrode D3 of the second pixel PXb may be electrically connected to the auxiliary initialization voltage line VL3a.

The auxiliary patterns AP1, AP2, and AP3 may include a first auxiliary pattern AP1 overlapping the driving voltage line VL1, a second auxiliary pattern AP2 overlapping the common voltage line VL2, and a third auxiliary pattern AP3 overlapping the initialization voltage line VL3. The first auxiliary pattern AP1, the second auxiliary pattern AP2, and the third auxiliary pattern AP3 may extend (e.g., longitudinally) in the second direction y. A plurality of the first auxiliary patterns AP1, the second auxiliary patterns AP2, and the third auxiliary patterns AP3 may be spaced from (e.g., offset from) each other in the second direction y. The first auxiliary pattern AP1, the second auxiliary pattern AP2, and the third auxiliary pattern AP3 may be connected to the driving voltage line VL1, the common voltage line VL2, and the initialization voltage line VL3 through the contact holes formed in the first and second insulating layers 120 and 140. Hence, resistance of the driving voltage line VL1, the common voltage line VL2, and the initialization voltage line VL3 may be reduced, RC delays of the driving voltage EL_{VDD}, the common voltage EL_{VSS}, and the initialization voltage V_{INT} may be reduced, and power consumption may also be reduced. The first auxiliary pattern AP1 may be connected to the auxiliary driving voltage line VL1a. Accordingly, the auxiliary driving voltage line VL1a may be connected to the driving voltage line VL1 through the first auxiliary pattern AP1, the driving voltage line VL1 and the auxiliary driving voltage line VL1a may be disposed in a mesh form, and the driving voltage EL_{VDD} at a uniform level may be transmitted to the display area DA. The first auxiliary pattern AP1 and the auxiliary driving voltage line VL1a may be integrally formed (e.g., formed as a unitary body).

Constituent elements included by the second conductive layer may be formed of a same material by the same process. The second conductive layer may include a metal such as copper (Cu), aluminum (Al), titanium (Ti), molybdenum (Mo), tungsten (W), and/or the like, and may have a single layer or a multi-layer structure. For example, the second conductive layer may have a triple-layered structure of titanium (Ti)/copper (Cu)/titanium (Ti).

A third insulating layer 150 may be disposed on the second conductive layer. The third insulating layer 150 may be referred to as a passivation layer. The third insulating layer 150 may be an inorganic insulating layer including an inorganic insulating material such as a silicon oxide, a silicon nitride, a silicon oxynitride, and/or the like, and may have a single layer or a multi-layer structure.

A fourth insulating layer 160 may be disposed on the third insulating layer 150. The fourth insulating layer 160 may be referred to as a planarization layer. The fourth insulating layer 160 may include an organic insulating material such as a general-purpose polymer such as poly(methyl methacrylate) (PMMA) or polystyrene (PS), a polymer derivative having a phenol-based group, an acryl-based polymer, an imide-based polymer (e.g., a polyimide), an acryl-based polymer, and a siloxane-based polymer.

A third conductive layer including pixel electrodes E1a, E1b, and E1c of the light-emitting device ED, a connection electrode CE, and an auxiliary common voltage line VL2a may be disposed on the fourth insulating layer 160. FIG. 9 shows the first conductive layer, the semiconductor layer, the second conductive layer, and the third conductive layer.

The pixel electrodes E1a, E1b, and E1c may include a pixel electrode E1a of the first pixel PXa, a pixel electrode E1b of the second pixel PXb, and a pixel electrode E1c of the third pixel PXc. The respective pixel electrodes E1a, E1b, and E1c may be connected to the second electrode S1 of the corresponding first transistor T1 through contact holes H1 formed in the third and fourth insulating layers 150 and 160.

The pixel electrodes E1a, E1b, and E1c may cover the first storage electrodes C1 of the corresponding pixels PXa, PXb, and PXc. The pixel electrode E1a may cover the entire or almost entire first storage electrode C1 of first pixel PXa, the pixel electrode E1b may cover the entire or almost entire first storage electrode C1 of the second pixel PXb, and the pixel electrode E1c may cover the entire or almost entire first storage electrode C1 of the third pixel PXc. As used herein, the covering of the almost entire first storage electrode C1 may refer to covering about 90% or more or about 95% or more of the planar region of the first storage electrode C1.

As the first storage electrode C1 is connected to the gate electrode G1, the voltage at the gate electrode G1 may be changed by a coupling (or parasitic capacitance) between the first storage electrode C1 and a conductor (e.g., a pixel electrode of another pixel, or data lines DLa, DLb, and DLc, etc.). The change of the voltage at the gate electrode G1 by the parasitic capacitance may influence the driving current output by the first transistor T1. Accordingly, display quality, for example, a color difference (or stains) may be generated by an increase of luminance according to the increase of the driving current. By shielding the first storage electrodes C1 of the pixels PXa, PXb, and PXc that correspond to the pixel electrodes E1a, E1b, and E1c according to some embodiments, parasitic capacitance that influences the operation of the first transistor T1 is reduced, and display quality is improved (e.g., increased).

When the first storage electrodes C1 are disposed so that the lines connecting the centers of the first storage electrodes C1 of the pixels PXa, PXb, and PXc may form a triangle, a ratio occupied by the area of the pixel electrodes E1a, E1b, and E1c covering the first storage electrodes C1 in the display area DA may be reduced (e.g., to about 43%). Accordingly, an opening OP3 may be enlarged to increase a space that may accommodate foreign substances, and generation of defects such as black spots caused by the foreign substances may be reduced in the fifth insulating layer 170 covering non-emission areas of the pixel electrodes E1a, E1b, and E1c.

In addition, it is desired that the area of the first storage electrode C1 be reduced to avoid the overlapping of the first storage electrode C1 of one pixel (e.g., the first pixel PXa) and the pixel electrode of another pixel (e.g., the pixel electrode E1c of the third pixel PXc) to reduce the parasitic capacitance, which may be generated when the first storage electrodes C1 of the pixels PXa, PXb, and PXc are disposed substantially in parallel to each other in the second direction y. Accordingly, capacity of the storage capacitors C_{ST} may be increased and a layout may be optimized.

The connection electrode CE may overlap the common voltage line VL2 and the second auxiliary pattern AP2. The connection electrode CE may have an octagonal shape in a plan view. The connection electrode CE are connected to the second auxiliary pattern AP2 through the contact holes formed in the third and fourth insulating layers 150 and 160. As the second auxiliary pattern AP2 is connected to the common voltage line VL2, the connection electrode CE may be electrically connected to the common voltage line VL2.

The auxiliary common voltage line VL2a may extend (e.g., longitudinally) in the first direction x, and may be connected to the connection electrode CE. Hence, the common voltage line VL2 and the auxiliary common voltage line VL2a may be disposed in a mesh form, and the common voltage EL_{VSS} at a uniform level may be transmitted to the display area DA. The auxiliary common voltage line VL2a and the connection electrode CE may be integrally formed (e.g., formed as a unitary body).

Constituent elements included by the third conductive layer may be formed of a same or substantially the same material by the same process. The third conductive layer may be made of a reflective conductive material or a semi-transmitting conductive material, and may be formed of a transparent conductive material. The third conductive layer may include a transparent conductive material such as an indium tin oxide (ITO), an indium zinc oxide (IZO), and/or the like. The third conductive layer may include a metal such as lithium (Li), calcium (Ca), aluminum (Al), silver (Ag), magnesium (Mg), gold (Au), and/or the like. The third conductive layer may have a multi-layered structure, for example, it may have a triple-layered structure of ITO/silver (Ag)/ITO.

A fifth insulating layer 170 may be disposed on the third conductive layer. The fifth insulating layer 170 may be referred to as a pixel defining layer or a bank. The fifth insulating layer 170 may include an organic insulating material such as an acryl-based polymer, an imide-based polymer, an a mode-based polymer, and/or the like. The fifth insulating layer 170 may include a black pigment. For example, the fifth insulating layer 170 may include a polyimide binder and a pigment that is a mixture of red, green, and blue. The fifth insulating layer 170 may include a cardo binder resin and a mixture of a lactam black pigment and a blue pigment. The fifth insulating layer 170 may include carbon black. The fifth insulating layer 170 including a black pigment may improve (e.g., increase) a contrast ratio, and may prevent or substantially reduce reflection caused by a metal layer disposed below the same.

The fifth insulating layer 170 may cover edges of the pixel electrodes E1a, E1b, and E1c. The fifth insulating layer 170 may cover the connection electrode CE and the auxiliary common voltage line VL2a. The fifth insulating layer 170 may have openings OPa, OPb, and OPc overlapping the pixel electrodes E1a, E1b, and E1c and an opening OP2 overlapping the connection electrode CE. The fifth insulating layer 170 may have an opening OP3 formed in a region that does not overlap the pixel electrodes E1a, E1b, and E1c, the connection electrode CE, and the auxiliary common voltage line VL2a. The openings OPa, OPb, OPc, OP2, and OP3 may be regions generated by removing the fifth insulating layer 170 in the third direction z that is a thickness direction.

The openings OPa, OPb, and OPc may correspond to the emission areas of the respective pixels PXa, PXb, and PXc. The opening OP2 may expose part of the connection electrode CE. The opening OP3 may provide a space for receiving foreign materials attachable to a surface of the display unit 100 when manufacturing the display unit 100. As described above, as the area of the pixel electrodes E1a, E1b, and E1c covering the first storage electrodes C1 may be reduced, the opening OP3 for receiving foreign materials may be increased on the fifth insulating layer 170 covering the non-emission areas of the pixel electrodes E1a, E1b, and E1c. The opening OP3 may reduce a region in which the fifth insulating layer 170 is formed and a volume of the fifth insulating layer 170, and hence, discharging of materials remaining in the fifth insulating layer 170 or decomposed materials into gas may be reduced. The discharged gas may be spread to a peripheral area and may be transmitted to the intermediate layer EL to deform or degrade the intermediate layer EL. When the intermediate layer EL is deformed or degraded, the emission areas of the pixels PXa, PXb, and PXc may shrink. As the volume of the fifth insulating layer 170 may be reduced by the opening OP3, gas discharged from the fifth insulating layer 170 may be reduced, and the defects such as the shrinkage may be reduced.

An intermediate layer EL may be disposed on the fourth conductive layer. The intermediate layer EL may be disposed on the pixels PXa, PXb, and PXc. The intermediate layer EL may be disposed in the display area DA. The intermediate layer EL may contact the pixel electrodes E1a, E1b, and E1c through the openings OPa, OPb, and OPc of the fifth insulating layer 170. The intermediate layer EL may have a contact hole H2 overlapping the opening OP2. The contact hole H2 may overlap the second auxiliary pattern AP2. The contact hole H2 may be surrounded by the opening OP2 and may be disposed in the opening OP2 in a plan view.

The intermediate layer EL may include an emission layer and a functional layer. The emission layer is a layer in which light is emitted through the combination of electrons and holes, and may include organic materials and/or inorganic materials that emit light of a set or predetermined color. The emission layer may include a light emitting material for emitting blue light. The emission layer may include a light emitting material for emitting red light or green light in addition to the blue light. The emission layer may include a plurality of emission layers, and the emission layers may include emission layers for emitting light of a same color or may include emission layers for emitting light of different colors. For example, the emission layers may have a structure in which two or three blue emission layers are stacked. The functional layer may include at least one of a hole injection layer, a hole transfer layer, an electron transfer layer, and an electron injection layer.

A common electrode E2 may be disposed on the intermediate layer EL. The common electrode E2 may be disposed on the pixels PXa, PXb, and PXc. The common electrode E2 may be consecutively disposed in the display area DA. The common electrode E2 may be connected to the connection electrode CE through the contact hole H2 formed in the intermediate layer EL. To connect the common electrode E2 and the connection electrode CE, the contact hole H2 of the intermediate layer EL may be formed by a laser drilling process. For example, by forming the intermediate layer EL, irradiating laser beams to the intermediate layer EL overlapping the opening OP2, and removing the same, the contact hole H2 penetrating the intermediate layer EL in the third direction z that is the thickness direction. Accordingly, the connection electrode CE overlapping the contact hole H2 may be exposed. When the common electrode E2 is formed, the common electrode E2 may be connected to the connection electrode CE through the contact hole H2. As the connection electrode CE is connected to the auxiliary common voltage line VL2a, the common electrode E2 may receive the common voltage EL_{VSS} through the connection electrode CE. Hence, as the common electrode E2 may uniformly receive the common voltage EL_{VSS} in the display area DA, a voltage drop caused by resistance of the common electrode E2 may be increased, and generation of a luminance deviation in the display area DA may be prevented or substantially reduced.

The common electrode E2 may include a metal such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), and/or the like. The common electrode E2 may include a transparent conductive oxide such as an indium tin oxide (ITO), an indium zinc oxide (IZO), and/or the like. The common electrode E2 may have a multi-layered structure, for example, it may have a double-layered structure of magnesium (Mg)/silver (Ag).

The pixel electrodes E1a, E1b, and E1c, the intermediate layer EL, and the common electrode E2 may constitute a light-emitting device ED, which may be an organic light emitting diode. The pixel electrodes E1a, E1b, and E1c may be individually provided for the respective corresponding pixels PXa, PXb, and PXc and may receive driving currents. The common electrode E2 may be provided in common to the pixels PXa, PXb, and PXc and may receive a common voltage. The pixel electrodes E1a, E1b, and E1c may be anodes that are hole injection electrodes, the common electrode E2 may be a cathode that is an electron injection electrode, and vice versa. The openings OPa, OPb, and OPc of the fifth insulating layer 170 may correspond to the emission area of the light-emitting device ED.

An encapsulation layer 190 may be disposed on the common electrode E2. The encapsulation layer 190 may seal the light-emitting devices ED, and may prevent moisture or oxygen from permeating from the outside or substantially reduce such permeation. The encapsulation layer 190 may cover the display area DA, and an edge of the encapsulation layer 190 may be disposed in the non-display area NA.

The encapsulation layer 190 may be a thin film encapsulation layer including a first inorganic layer 191, an organic layer 192, and a second inorganic layer 193. The first inorganic layer 191 and the second inorganic layer 193 may generally prevent or substantially reduce permeation of moisture, and the organic layer 192 may generally planarize a surface of the encapsulation layer 190, particularly a surface of the second inorganic layer 193 in the display area DA. The first inorganic layer 191 and the second inorganic layer 193 may include an inorganic insulating material such as a silicon oxide, a silicon nitride, and/or the like. The organic layer 192 may include an organic material such as an acryl-based resin, a methacryl-based resin, polyisoprene, a vinyl-based resin, an epoxy-based resin, urethane-based resin, a cellulose-based resin, a perylene-based resin, and/or the like.

FIG. 10 shows a cross-sectional view of a display area in alight emitting display device according to some embodiments of the present disclosure.

Referring to FIG. 10, the display panel 10 may include a display unit 100, a color conversion unit 200, and a filler 400 disposed between the display unit 100 and the color conversion unit 200.

The display unit 100 may include a substrate 110, transistors TR formed in the substrate 110, and a light-emitting devices ED connected to the transistors TR. The transistor TR may include a semiconductor AT, a gate electrode GE, a first electrode DE, and a second electrode SE. The first electrode DE may be connected to a first region of the semiconductor AT, and the second electrode SE may be connected to a second region of the semiconductor AT and the light blocking pattern LB. The shown transistor (TR) may be the first transistor T1. The pixel electrodes E1a, E1b, and E1c may be connected to second electrodes SE of the pixels PXa, PXb, and PXc. The fifth insulating layer 170 may have openings OPa, OPb, and OPc that correspond to the emission areas of the pixels PXa, PXb, and PXc, respectively. The intermediate layer EL and the common electrode E2 may be continuously disposed on the pixels PXa, PXb, and PXc. The encapsulation layer 190 may cover the light-emitting devices ED. The detailed characteristics of the display unit 100 have been described so the color conversion unit 200 and the filler 400 will now be described.

The color conversion unit 200 may be disposed on the encapsulation layer 190 of the display unit 100.

The color conversion unit 200 may include a substrate 210. The substrate 210 may include an insulating material such as glass or plastic, for example, the substrate 110 may be a glass substrate.

Color filters 230a, 230b, and 230c may be disposed on the substrate 210 in a direction that faces the display unit 100. The color filters 230a, 230b, and 230c may respectively overlap the openings OPa, OPb, and OPc of the fifth insulating layer 170 in the display area DA. The color filters 230a, 230b, and 230c may include a first color filter 230a for transmitting light with a first wavelength and absorbing light with other wavelengths, a second color filter 230b for transmitting light with a second wavelength and absorbing light with other wavelengths, and a third color filter 230c for transmitting light with a third wavelength and absorbing light with other wavelengths. The first color filter 230a, the second color filter 230b, and the third color filter 230c may overlap the first pixel PXa, the second pixel PXb, and the third pixel PXc. Accordingly, purity of the light with a first wavelength (corresponding to the first pixel PXa) emitted toward the outside of the display panel 10, the light with a second wavelength (corresponding to the second pixel PXb), and the light with a third wavelength (corresponding to the third pixel PXc) may be increased. The light with a first wavelength, the light with a second wavelength, and the light with a third wavelength may be red light, green light, and blue light, respectively.

The first color filter 230a, the second color filter 230b, and the third color filter 230c may overlap each other and may form a light blocking region on border portions of the pixels PXa, PXb, and PXc. As shown, the first color filter 230a, the second color filter 230b, and the third color filter 230c may overlap each other to form a light blocking region, and two thereof may overlap each other to form a light blocking region. The first color filter 230a, the second color filter 230b, and the third color filter 230c may overlap each other to form a light blocking region in the non-display area NA. The third color filter 230c, the first color filter 230a, and the second color filter 230b are stacked in order on the substrate 210, and they may be stacked in other orders. Instead of overlapping the color filters 230a, 230b, and 230c, the light blocking region may be provided by forming a light blocking member.

A low refractive index layer 240 may be disposed on the color filters 230a, 230b, and 230c. The low refractive index layer 240 may be disposed to cover the substrate 210. The low refractive index layer 240 may include an organic material or an inorganic material with a refractive index. The refractive index of the low refractive index layer 240 may be about 1.1 to about 1.3. The low refractive index layer 240 may be disposed on positions that are different from what is shown. For example, the low refractive index layer 240 may be disposed among the color converting layers 270a and 270b, the transmission layer 270c, and the second capping layer 280. The color conversion unit 200 may include a plurality of low refractive index layers. For example, the color conversion unit 200 may further include a low refractive index layer disposed among the color converting layers 270a and 270b, the transmission layer 270c, and the second capping layer 280 in addition to the low refractive index layer 240 disposed among the color filters 230a, 230b, and 230c and the first capping layer 250.

A first capping layer 250 may be disposed on the low refractive index layer 240. The first capping layer 250 may be disposed to cover the low refractive index layer 240 and may protect the low refractive index layer 240. The first capping layer 250 may include an inorganic insulating material such as a silicon oxide, a silicon nitride, a silicon oxynitride, and/or the like, and may have a single layer or a multi-layer structure.

A bank 260 may be disposed on the first capping layer 250. The bank 260 may be disposed in the display area DA, and may overlap the fifth insulating layer 170. The bank 260 may overlap the light blocking region overlapping the first color filter 230a, the second color filter 230b, and the third color filter 230c. The bank 260 may be disposed on the border portions of the pixels PXa, PXb, and PXc. The bank 260 may partition the pixel area. The bank 260 may include an organic insulating material such as an acryl-based polymer, an imide-based polymer, an amide-based polymer, and/or the like. The bank 260 may be a black bank including a colored pigment such as a black pigment, and it may be transparent.

A first color converting layer 270a, a second color converting layer 270b, and a transmission layer 270c may be disposed on the first capping layer 250. The first color converting layer 270a, the second color converting layer 270b, and the transmission layer 270c may be disposed in a space (i.e., an opening of the bank 260) defined by the bank 260. The first color converting layer 270a, the second color converting layer 270b, and the transmission layer 270c may be partitioned or divided by the bank 260. The first color converting layer 270a, the second color converting layer 270b, and the transmission layer 270c may be formed by an inkjet printing process.

The first color converting layer 270a may overlap the first color filter 230a. The first color converting layer 270a may overlap the light-emitting device ED that corresponds to the first pixel PXa, and may convert light input by the light-emitting device ED into light with a first wavelength. The light with a first wavelength may be red light with a maximum light-emitting peak wavelength of about 600 nm to about 650 nm, for example, about 620 nm to about 650 nm.

The second color converting layer 270b may overlap the second color filter 230b. The second color converting layer 270b may overlap the light-emitting device ED that corresponds to the second pixel PXb, and may convert light input by the light-emitting device ED into light with a second wavelength. The light with a second wavelength may be green light with the maximum light-emitting peak wavelength of about 500 nm to about 550 nm, for example, about 510 nm to about 550 nm.

The transmission layer 270c may overlap the third color filter 230c. The transmission layer 270c may overlap the light-emitting device ED that corresponds to the third pixel PXc, and may transmit light input by the light-emitting device ED. The light having passed through the transmission layer 270c may be light with a third wavelength. The light with a third wavelength may be blue light with the maximum light-emitting peak wavelength of about 380 nm to about 480 nm, for example, about 420 nm or more, about 430 nm or more, about 440 nm or more, or about 445 nm or more, and about 470 nm or less, about 460 nm or less, or about 455 nm or less.

The first color converting layer 270a and the second color converting layer 270b may respectively include first quantum dots and second quantum dots. For example, the light input to the first color converting layer 270a may be converted into the light with a first wavelength by the first quantum dots and may be discharged. The light input to the second color converting layer 270b may be converted into the light with a second wavelength by the second quantum dots and may be discharged. The first color converting layer 270a, the second color converting layer 270b, and the transmission layer 270c may include scatterers. The scatterers may scatter the light input to the first color converting layer 270a, the second color converting layer 270b, and the transmission layer 270c to increase light efficiency.

The first quantum dot and the second quantum dot (the quantum dots will also be referred to as semiconductor nanocrystals) may independently include a group II-VI compound, a group III-V compound, a group IV-VI compound, a group IV element or compound, a group I-III-VI compound, a group II-III-VI compound, a group I-II-IV-VI compound, or a combination thereof.

The group II-VI compound may be selected from among a binary compound selected from among CdSe, CdTe, ZnS, ZnSe, ZnTe, ZnO, HgS, HgSe, HgTe, MgSe, MgS, and a mixture thereof; a tertiary compound selected from among AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from among HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof. The group II-VI compound may further include a group III metal.

The group III-V compound may be selected from among a binary compound selected from among GaN, GaP, GaAs, GaSb, AlN, AlP, AlAs, AlSb, InN, InP, InAs, InSb, and a mixture thereof; a tertiary compound selected from among GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and a mixture thereof; and a quaternary compound selected from among GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and a mixture thereof. The group III-V compound may further include a group II metal (e.g., InZnP).

The group IV-VI compound may be selected from among a binary compound selected from among SnS, SnSe, SnTe, PbS, PbSe, PbTe, and a mixture thereof; a tertiary compound selected from among SnSeS, SnSeTe, SnSTe, PbSeS, PbSeTe, PbSTe, SnPbS, SnPbSe, SnPbTe, and a mixture thereof; and a quaternary compound selected from among SnPbSSe, SnPbSeTe, SnPbSTe, and a mixture thereof.

The group IV element or compound may be selected from among a unary compound selected from among Si, Ge, and a combination thereof; and a binary compound selected from among SiC, SiGe, and a combination thereof.

The group I-III-VI compound may be selected from among CuInSe₂, CuInS₂, CuInGaSe, and CuInGaS.

The group II-III-VI compound may be selected from among ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and a combination thereof.

The group I-II-IV-VI compound may be selected from among CuZnSnSe and CuZnSnS.

The quantum dot may not include cadmium. The quantum dot may include a semiconductor nanocrystal based on the group III-V compound including indium and phosphorus. The group III-V compound may further include zinc. The quantum dot may include a semiconductor nanocrystal based on the group II-VI compound including a chalcogen (e.g., sulfur, selenium, tellurium, or a combination thereof) and zinc.

Regarding the quantum dot, the above-described binary compound, tertiary compound, and/or quaternary compound may exist in the particles with uniform concentration, or may exist in the same particles with a concentration distribution partially divided into some states. Further, the color conversion media layer may have a core/shell structure where one quantum dot surrounds another quantum dot. An interface between the core and the shell may have a concentration gradient such that a concentration of an element existing in the shell is gradually reduced nearing the center thereof.

In some embodiments, the quantum dot has a core-shell structure including a core including the above-described nanocrystal and a shell surrounding the core. The shell of the quantum dot may function as a protective layer for maintaining the semiconductor characteristic by preventing or substantially reducing chemical denaturation of the core and/or a charging layer for providing an electrophoretic characteristic to the quantum dot. The shell may be a single layer or a multilayer structure. An interface between the core and the shell may have a concentration gradient such that a concentration of an element existing in the shell is gradually reduced nearing the center thereof. Examples of the shell of the quantum dot include a metallic or non-metallic oxide, a semiconductor compound, or a combination thereof.

The metallic or non-metallic oxide may exemplify binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or the like, or tertiary compounds such as MgAl₂O₄, CoFe₂O₄, NiFe₂O₄, CoMn₂O₄, and/or the like.

The semiconductor compound may be exemplified by CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like.

The quantum dot may have a full width at half maximum of a light-emitting wavelength spectrum that is less than about 45 nm, less than about 40 nm, or less than about 30 nm, and it may improve (e.g., increase) color purity or color reproducibility within this range. Light emitted through the quantum dot is output in all directions, thereby improving a viewing angle.

Regarding the quantum dot, a shell material and a core material may have different energy bandgaps. For example, the energy bandgap of the shell material may be greater or less than the energy bandgap of the core material. The quantum dot may have a multi-layered shell. Regarding the multi-layered shell, the energy bandgap of an outer layer may be greater than the energy bandgap of an inner layer (i.e., a layer that is nearest the core). Regarding the multi-layered shell, the energy bandgap of the outer layer may be less than the energy bandgap of the inner layer.

A shape of the quantum dot is not specifically limited. For example, the shape of the quantum dot may include a sphere, a polyhedron, a pyramid, a multipod, a square, a cuboid, a nanotube, a nanorod, a nanowire, a nanosheet, or a combination thereof.

The quantum dot may include an organic ligand (e.g., having a hydrophobic residue and/or a hydrophilic residue). The organic ligand residue may be combined to the surface of the quantum dot. The organic ligand may include RCOOH, RNH₂, R₂NH, R₃N, RSH, R₃PO, R₃P, ROH, RCOOR, RPO(OH)₂, RHPOOH, R₂POOH, or combinations thereof. Here, R may independently be a C₃ to C₄₀ substituted or unsubstituted aliphatic hydrocarbon group such as a C₃ to C₄₀ (e.g., C₅ to C₂₄) substituted or unsubstituted alkyl group, or a substituted or unsubstituted alkenyl group, a C₆ to C₄₀ (e.g., C₆ to C₂₀) substituted or unsubstituted aromatic hydrocarbon group such as a C₆ to C₄₀ substituted or unsubstituted aryl group, or a combination thereof.

Examples of the organic ligand may include thiol compounds such as methane thiol, ethane thiol, propane thiol, butane thiol, pentane thiol, hexane thiol, octane thiol, dodecane thiol, hexadecane thiol, octadecane thiol, benzyl thiol, and/or the like; amines such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, trioctylamine, and/or the like; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, benzoic acid, and/or the like; phosphine compounds such as methyl phosphine, ethyl phosphine, propyl phosphine, butyl phosphine, pentyl phosphine, octyl phosphine, dioctyl phosphine, tributyl phosphine, trioctyl phosphine, and/or the like; phosphine compounds or their oxide compounds such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, diphenyl phosphine, a triphenyl phosphine compound and/or oxide compounds thereof, C₅ to C₂₀ alkyl phosphinic acids such as hexylphosphinic acid, octylphosphinic acid, dodecanephosphinic acid, tetradecanephosphinic acid, hexadecanephosphinic acid, octadecanephosphinic acid, C₅ to C₂₀ alkyl phosphonic acids, and/or the like. The quantum dot may include the organic ligand alone or as a mixture of at least one kind. The hydrophobic organic ligand may not include a photopolymerizable residue (e.g., an acrylate or methacrylate).

A second capping layer 280 may be disposed on the bank 260. The second capping layer 280 may cover the substrate 210. The second capping layer 280 may cover the first color converting layer 270a, the second color converting layer 270b, and the transmission layer 270c. The second capping layer 280 may include an inorganic insulating material such as a silicon oxide, a silicon nitride, a silicon oxynitride, and/or the like, and may have a single layer or a multi-layer structure.

The low refractive index layer 240, the first capping layer 250, and the second capping layer 280 may cover lateral sides of the color filters 230a, 230b, and 230c on the edge portion of the color conversion unit 200. The low refractive index layer 240, the first capping layer 250, and the second capping layer 280 may be formed up to the edge of the substrate 210, and the low refractive index layer 240 may contact the substrate 210 at the edge of the color conversion unit 200. The low refractive index layer 240, the first capping layer 250, and the second capping layer 280 may form a blocking member for preventing moisture and oxygen from permeating from the edge of the color conversion unit 200 or substantially reduce such permeation.

A filler 400 may be disposed between the color conversion unit 200 and the display unit 100. The filler 400 may fill (e.g., charge) a space between the display unit 100 and the color conversion unit 200 to increase pressing resistance between the display unit 100 and the color conversion unit 200. A first side of the filler 400 may contact the second capping layer 280, and a second side of the filler 400 may contact the encapsulation layer 190. The filler 400 may be formed when a charging material is applied on the second capping layer 280 and the display unit 100 is overlapped thereon and is cured. The filler 400 may include an organic material such as an epoxy resin, and/or the like.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the present disclosure as defined by the appended claims and equivalents thereof.

What is claimed is:

1. A light emitting display device comprising:
a first pixel, a second pixel, and a third pixel for emitting light of different colors, each of the first to third pixels comprising:
a lower storage electrode,
an upper storage electrode overlapping the lower storage electrode and forming a storage capacitor with the lower storage electrode, and
a pixel electrode overlapping the upper storage electrode, and
wherein the upper storage electrode of the first pixel and the upper storage electrode of the third pixel are arranged in a first direction, and the upper storage electrodes of the first pixel and the third pixel and the upper storage electrode of the second pixel are arranged in a second direction crossing the first direction.

2. The light emitting display device of claim 1, wherein lines connecting centers of the upper storage electrodes of the first pixel, the second pixel, and the third pixel form an acute-angled triangle, and
wherein a line connecting centers of the upper storage electrodes of the first pixel and the third pixel is parallel to the first direction, a line connecting centers of the upper storage electrodes of the first pixel and the second pixel forms an acute angle with respect to the first direction, and a line connecting centers of the upper storage electrodes of the second pixel and the third pixel forms an obtuse angle with respect to the first direction.

3. The light emitting display device of claim 1, further comprising:
a first data line, a second data line, and a third data line extending in the second direction, and configured to transmit data voltages to the first pixel, the second pixel, and the third pixel, respectively,
wherein the upper storage electrodes of the first pixel, the second pixel, and the third pixel are between the first data line and the second data line.

4. The light emitting display device of claim 1, further comprising:
a driving voltage line extending in the second direction and configured to transmit a driving voltage, and
an auxiliary driving voltage line extending in the first direction and connected to the driving voltage line,
wherein each of the first pixel, the second pixel, and the third pixel comprises a first transistor, the first transistor comprising a first semiconductor, a first gate electrode, a first electrode, and a second electrode,
wherein the first gate electrode is connected to the upper storage electrode, and
wherein the first electrode is a protrusion of the auxiliary driving voltage line.

5. The light emitting display device of claim 4, wherein the first semiconductor comprises a channel region, and a first region and a second region respectively on a first side and a second side of the channel region in the second direction, and
wherein a portion of the first gate electrode overlapping the first semiconductor extends in the first direction.

6. The light emitting display device of claim 4, further comprising:
an auxiliary pattern overlapping the driving voltage line and connected to the driving voltage line,
wherein the auxiliary pattern and the auxiliary driving voltage line are integrally formed.

7. The light emitting display device of claim 4, further comprising:
a first gate line extending in the first direction and configured to transmit a first scan signal;
a second gate line extending in the first direction and configured to transmit a second scan signal;
an initialization voltage line extending in the second direction and configured to transmit an initialization voltage; and
auxiliary initialization voltage line extending in the first direction and connected to the initialization voltage line,
wherein the first gate line, the second gate line, and the auxiliary initialization voltage line are between the upper storage electrode of the second pixel and the upper storage electrodes of the first pixel and the third pixel.

8. The light emitting display device of claim 7, wherein each of the first pixel, the second pixel, and the third pixel comprises a second transistor, the second transistor comprising a second semiconductor and a second gate electrode,
wherein in each of the first pixel, the second pixel, and the third pixel, the second semiconductor is integrally formed with the upper storage electrode, and
wherein the second gate electrode of the first pixel and the second gate electrode of the third pixel are protrusions of the first gate line, and the second gate electrode of the second pixel is connected to the first gate line by a connector.

9. The light emitting display device of claim 8, wherein each of the first pixel, the second pixel, and the third pixel further comprises a third transistor, the third transistor comprising a third semiconductor and a third gate electrode, and
wherein the third gate electrode of the second pixel is a protrusion of the second gate line, and the third gate electrode of the first pixel and the third gate electrode of the third pixel are connected to the second gate line by a connector.

10. The light emitting display device of claim 1, further comprising:
a common voltage line extending in the second direction and configured to transmit a common voltage;
an auxiliary pattern connected to and overlapping the common voltage line;
a connection electrode connected to and overlapping the auxiliary pattern; and
an auxiliary common voltage line extending in the first direction and integrally formed with the connection electrode.

11. A light emitting display device comprising a unit pixel comprising a first pixel, a second pixel, and a third pixel for emitting light of different colors, the unit pixel further comprising:
a substrate;
lower storage electrodes of the first, second, and third pixels on the substrate;
a first insulating layer on the lower storage electrodes;
upper storage electrodes of the first, second, and third pixels on the first insulating layer;
a third insulating layer on the upper storage electrodes;
a fourth insulating layer on the third insulating layer;
pixel electrodes of the first, second, third pixels on the fourth insulating layer and overlapping the upper storage electrodes; and
a fifth insulating layer having openings overlapping the pixel electrodes,
wherein the upper storage electrode of the first pixel overlaps the upper storage electrode of the third pixel in a first direction, and the upper storage electrodes of the first and third pixels overlap the upper storage electrode of the second pixel in a second direction crossing the first direction.

12. The light emitting display device of claim 11, wherein lines connecting centers of the upper storage electrodes of the first, second, and third pixels form an acute-angled triangle, and
wherein a line connecting centers of the upper storage electrodes of the first and third pixels is parallel to the first direction, a line connecting centers of the upper storage electrodes of the first and second pixels forms an acute angle with respect to the first direction, and a line connecting centers of the upper storage electrodes of the second and third pixels forms an obtuse angle with respect to the first direction.

13. The light emitting display device of claim 11, further comprising:
a first data line, a second data line, and a third data line extending in the second direction between the substrate and the first insulating layer, and configured to transmit data voltages to the first pixel, the second pixel, and the third pixel, respectively, and
wherein the upper storage electrodes of the first, second, and third pixels are between the first data line and the second data line in a plan view.

14. The light emitting display device of claim 11, further comprising:
a driving voltage line extending in the second direction between the substrate and the first insulating layer and configured to transmit a driving voltage;
a second insulating layer between the first insulating layer and the third insulating layer; and
an auxiliary driving voltage line extending in the first direction between the second insulating layer and the third insulating layer and connected to the driving voltage line,
wherein each of the first, second, and third pixels comprises a first transistor comprising a first semiconductor, a first gate electrode, a first electrode, and a second electrode, and
wherein the first electrode is a protrusion of the auxiliary driving voltage line.

15. The light emitting display device of claim 14, wherein the first semiconductor is between the first insulating layer and the second insulating layer,
wherein the first semiconductor comprises a channel region, and a first region and a second region respectively on a first side and a second side of the channel region in the second direction, and
wherein a portion of the first gate electrode overlapping the first semiconductor extends in the first direction.

16. The light emitting display device of claim 14, further comprising:
an auxiliary pattern between the second insulating layer and the third insulating layer and connected to the driving voltage line and the auxiliary driving voltage line.

17. The light emitting display device of claim 14, further comprising:
a first gate line extending in the first direction between the second insulating layer and the third insulating layer and configured to transmit a first scan signal;
a second gate line extending in the first direction between the second insulating layer and the third insulating layer and configured to transmit a second scan signal;
an initialization voltage line extending in the second direction between the substrate and the first insulating layer and configured to transmit an initialization voltage; and
an auxiliary initialization voltage line extending in the first direction between the second insulating layer and the third insulating layer and connected to the initialization voltage line,
wherein the first gate line, the second gate line, and the auxiliary initialization voltage line are between the upper storage electrode of the second pixel and the upper storage electrodes of the first and third pixels in a plan view.

18. The light emitting display device of claim 17, wherein each of the first, second, and third pixels comprises a second transistor the second transistor comprising a second semiconductor and a second gate electrode,
wherein in each of the first, second, and third pixels, the second semiconductor is integrally formed with the upper storage electrode,
wherein the second gate electrode of the first pixel and the second gate electrode of the third pixel are protrusions of the first gate line, and
wherein the second gate electrode of the second pixel is connected to the first gate line by a connector between the substrate and the first insulating layer.

19. The light emitting display device of claim 18, wherein each of the first, second, and third pixels further comprises a third transistor, the third transistor comprising a third semiconductor and a third gate electrode, and
wherein the third gate electrode of the second pixel is a protrusion of the second gate line, and the third gate electrode of the first pixel and the third gate electrode of the third pixel are connected to the second gate line by a connector between the substrate and the first insulating layer.

20. The light emitting display device of claim 11, further comprising:
a common voltage line extending in the second direction between the substrate and the first insulating layer and configured to transmit a common voltage;
an auxiliary pattern between the first insulating layer and the third insulating layer and connected to the common voltage line;
a connection electrode on the fourth insulating layer and connected to the auxiliary pattern; and
an auxiliary common voltage line extending in the first direction on the fourth insulating layer and connected to the connection electrode.
